(19) United States
(12) Patent Application Publication
(10) Pub. No.: US 2014/0363016 A1
(43) Pub. Date: Dec. 11, 2014

(54) AMPLIFIED HEADPHONE SYSTEM WITH INTEGRATED POWER AMPLIFIER

(71) Applicant: IdeaVillage Products Corp., Wayne, NJ (US)

(72) Inventor: Greg E. Blonder, Summit, NJ (US)

(21) Appl. No.: 14/468,984

(22) Filed: Aug. 26, 2014

Related U.S. Application Data
(63) Continuation-in-part of application No. 13/815,538, filed on Mar. 8, 2013.
(60) Provisional application No. 61/869,824, filed on Aug. 26, 2013.

(51) Int. Cl. H04R 1/10; H03F 3/181

(52) U.S. Cl. CPC H04R 1/1041; H03F 3/181
USPC 381/74

(57) ABSTRACT

A music playing and listening apparatus including at least one speaker, the speaker having at least two listening modes, at least one mode switch, at least one amplifier, at least one power source, and at least one power diversion switch.

### CROSS-REFERENCE TO RELATED APPLICATIONS

This application is a continuation-in-part of U.S. application Ser. No. 13/815,538, filed Mar. 8, 2013. This application claims the benefit of U.S. Provisional Application No. 61/869,824, filed on Aug. 26, 2013. U.S. application Ser. No. 13/815,538 and U.S. Provisional Application No. 61/869,824 are both hereby incorporated by reference in their entireties.

### TECHNICAL FIELD

Embodiments of the present disclosure relate to a music listening and playing apparatus and more specifically, to a headphone including an audio power amplifier.

### BACKGROUND

Conventional wearable audio devices such as headphones (i.e. headsets) were designed to be powered directly from the output of an audio source, such as a stereo system, portable music player, or smartphone. These audio sources are typically limited to less than 100 mW of power, and a 1 Volt signal amplitude.

Typically, the power to drive the amplifier (or external speaker activated when the headset is rotated into the speaker mode position) is derived from a 3.7 VDC lithium rechargeable battery incorporated into at least one of the speaker housings.

Although rechargeable lithium batteries are extremely popular due to their high power capacity to weight ratio, lack of “memory effect”, and large number of recharge cycles, power amplifiers are more efficient and more linear when operated at higher voltage than those supplied by a typical rechargeable battery.

### SUMMARY

In an embodiment, a music playing and listening apparatus comprises at least one speaker, the speaker having at least two listening modes, at least one mode switch, at least one amplifier, at least one power source, and at least one power diversion switch.

In another embodiment, a music playing and listening apparatus has a first power source which is integral to the apparatus. In yet another embodiment, a music playing and listening apparatus has a second power source that is external to the apparatus. In a further embodiment, a music playing and listening apparatus has an audio input receiver. In an even further embodiment, a music playing and listening apparatus has a power input receiver. In still a further embodiment, a music playing and listening apparatus has a power diversion switch configured to route power from the first power source to the amplifier in a first condition. In still another embodiment, a music playing and listening apparatus has a power diversion switch configured to route power from the second power source to the amplifier in a second condition. In still yet another embodiment, a music playing and listening apparatus includes at least two operating conditions and where the performance of the amplifier is improved in the second condition.

In still a further embodiment, a music playing and listening apparatus comprises a headband having opposing ends, at least two connectors, each of the connectors having at least two arms, a first arm being shorter than a second arm, at least two speakers, each of the speakers having opposing sides and comprising an audio output element on a first side and a compartment on a second side, the first and second arms of each of the connectors being pivotally attached to a portion of each of the speakers to thereby allow rotation of the speakers, each of the audio output elements of each of the speakers generally face one another during a first music listening mode, each of the speakers being rotatable about the first and second arms of each of the connectors to thereby allow each of the audio output elements of each of the speakers to turn away from one another during a second music playing mode, the rotation of the speakers allowing for changes in modes, at least one amplifier; and at least one power diversion switch.

In an embodiment of the present disclosure, a headphone system includes a power amplifier. The amplifier may be configured to deliver greater than three watts of power at approximately 4 Volts, although the actual power and voltage maybe varied and still be within the scope of this disclosure.

In an embodiment, the power to drive the amplifier in a first condition is derived from a first power source (i.e. a battery such as a 3.7 VDC lithium rechargeable battery). If rechargeable batteries are used, the battery may be recharged by coupling the headphone to an external power source. In a second condition, the power is derived from a second power source such as an external power supply. In an embodiment the headphone includes a connector for an external power supply such as a USB jack configured to receive power from an external power source such as a standard 5 VDC USB port of a computing device.

In an embodiment, the external power source (e.g., a 5 volt USB power port of an external device) provides power to the headphone via an external power connector. The external power may be connected to a battery recharging circuit, which converts the voltage (e.g. 5V) of the external power supply to an appropriate voltage for recharging a rechargeable battery. The output of the rechargeable battery is configured to power headphone electronics.

### BRIEF DESCRIPTION OF THE DRAWINGS

The accompanying drawings are included to provide a further understanding of the present disclosure. These drawings are incorporated in and constitute a part of this specification, illustrate one or more embodiments of the present disclosure and together with the description, serve to explain the principles of the present disclosure.

FIG. 1 is a perspective view of the apparatus of the present disclosure in a music listening mode on a user's head;

FIG. 2 is a perspective view of the apparatus of FIG. 1 in a music playing mode around a user's neck;

FIG. 3 is a perspective view of the apparatus of FIG. 1 in a music playing mode when the apparatus is placed on a surface;

FIG. 4 illustrates an embodiment of electronics for the disclosure without a power diversion switch;

FIG. 5 illustrates exemplary graphs depicting the operational performance of an amplifier; and

FIG. 6 illustrates an embodiment of electronics for the disclosure with a power diversion switch;

FIG. 7a illustrates an embodiment of electronics for the disclosure where the left and right speakers are not amplified; and

FIG. 7b illustrates an embodiment of electronics for the disclosure where the left and right speakers are amplified.

Among those benefits and improvements that have been disclosed, other objects and advantages of this disclosure will become apparent from the following description taken in conjunction with the accompanying drawings. The drawings constitute a part of this specification and include exemplary embodiments of the present disclosure and illustrate various objects and features thereof.

### DETAILED DESCRIPTION

Embodiments of the present disclosure are disclosed herein; however, it is to be understood that the disclosed embodiments are merely exemplary of the disclosure that may be embodied in various forms. The figures are not necessarily to scale, some features may be exaggerated to show details of particular components. Therefore, specific structural and functional details disclosed herein are not to be interpreted as limiting, but merely as a basis for the claims and as a representative basis for teaching one skilled in the art to variously employ the present disclosure. Although reference is made throughout this specification to a 5V power source and a nominal 3.7 volt rechargeable lithium ion battery the reference is exemplary only. The supply voltage may be at any suitable voltage and the battery voltage need not be 3.7 volts (the voltage may vary based on the battery technology used), the battery need not be rechargeable, and the battery need not be lithium ion. Variations of voltage of the power source, changes in battery type (rechargeable vs primary), battery technology, and battery voltage are all within the scope of this invention.

The present disclosure relates to headphones including a power diversion switch configured to deliver voltage from an external source (e.g. a 5 Volt USB power source) to the electronics of the headphone, including an amplifier, when the headphone is connected to an external power source for charging an internal battery (e.g., a 3.7 Volt Lithium rechargeable battery). In this regard, the power diversion switch delivers a higher voltage to the amplifier when the headphone is connected to the external power source, thereby resulting in a louder and higher fidelity playback when the headphone is being charged. Advantageously, the convertible headphone amplifier runs off the internal 3.7 V battery while not charging, and operates the headphone electronics at 5V when connected to an external power source while charging the internal rechargeable battery. In operation, a user may position the headphone in “speaker mode” (e.g. with the speakers in the rotated position with the amplifier turned on) during charging, allowing the headphone to perform like standard desktop mini-speakers.

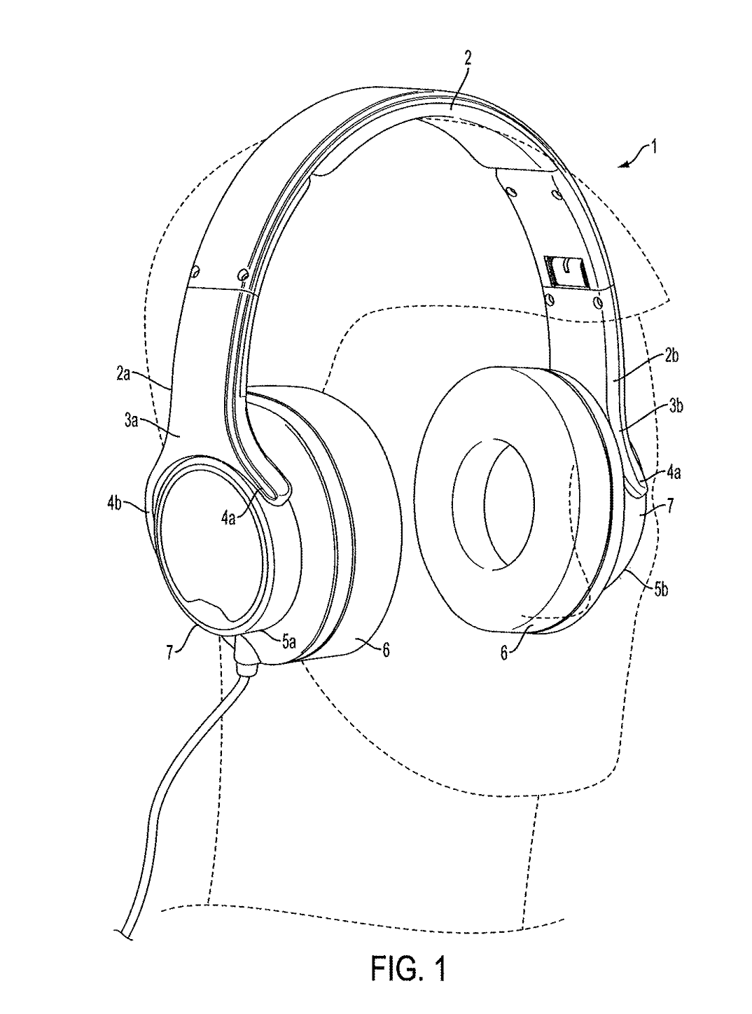

FIG. 1 illustrates the music listening and playing apparatus 1 of the present disclosure. The apparatus comprises a headband 2 having opposing ends, 2a and 2b, connectors 3a and 3b, each of the connectors having arm(s), 4a and 4b. The first arm 4a is shorter than a second arm 4b.

The apparatus 1 further comprises at least two speakers, 5a and 5b respectively, each of the speakers having opposing sides and comprising an audio output element 6 on a first side and a compartment 7 on a second side. The first and second arms, 4a and 4b, of each of the connectors are pivotally attached to a portion of each of the speakers, 5a or 5b, to thereby allow rotation of said speakers. In an embodiment, (not shown) a speaker (e.g. 5a or 5b) is rotatably attached to a single arm. Each of the audio output elements 6 of each of the speakers, 5a and 5b, generally face one another during a first music listening mode. In the music listening mode, the headband 2 is situated around the user's head and the audio output element 6 of each of the speakers, 5a and 5b, are generally facing the user's ears.

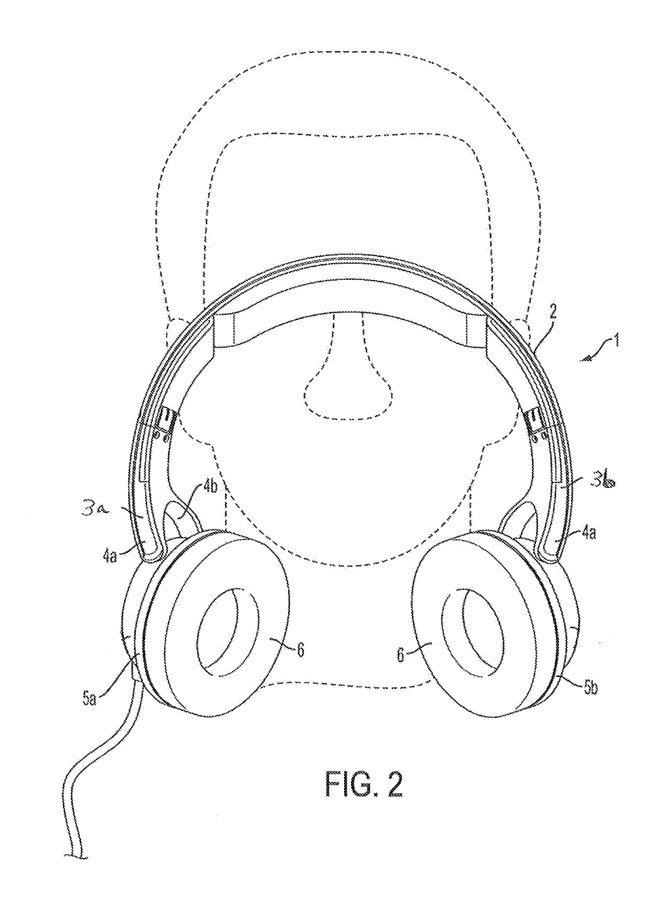

FIG. 2 depicts the second music playing mode of the apparatus 1 of the present disclosure. The apparatus 1 may be placed around the user's neck and supported by headband 2. Each of the speakers, 5a and 5b, are rotatable about the first and second arms, 4a and 4b, of each of the connectors, 3a and 3b, to thereby allow each of the audio output elements 6 of each of the speakers, 5a and 5b, to turn away from one another during the second music playing mode. The rotation of the speakers, 5a and 5b, allows for changes in modes.

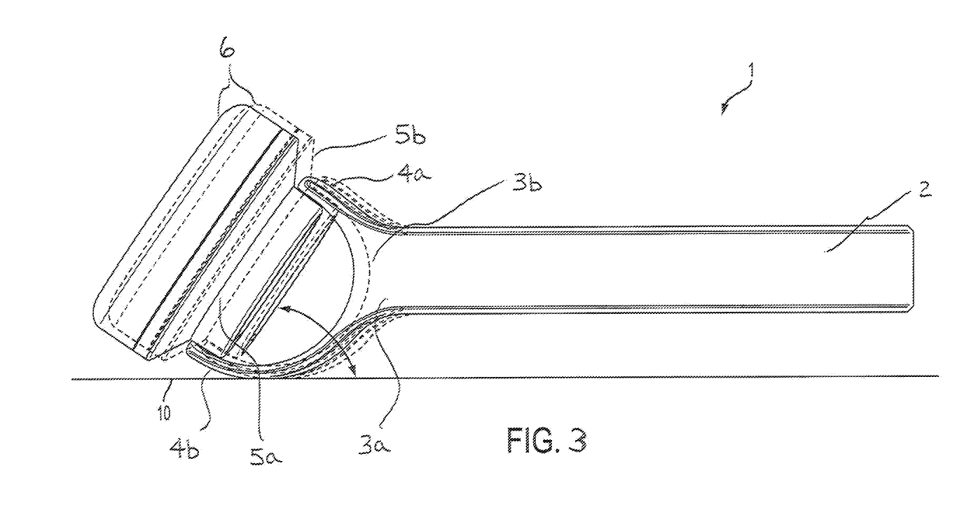

FIG. 3 shows another music playing mode where the apparatus 1 is set on a surface 10 and the headband 2 is generally parallel to the surface 10, although a portion of headband 2 may rest on surface 10. Speakers, 5a and 5b, are designed to be rotated about the first and second arms, 4a and 4b, of each of the connectors, 3a and 3b, to allow the audio output elements 6 of each of the speakers, 5a and 5b, to generally face away from the surface 10 during the second music playing mode.

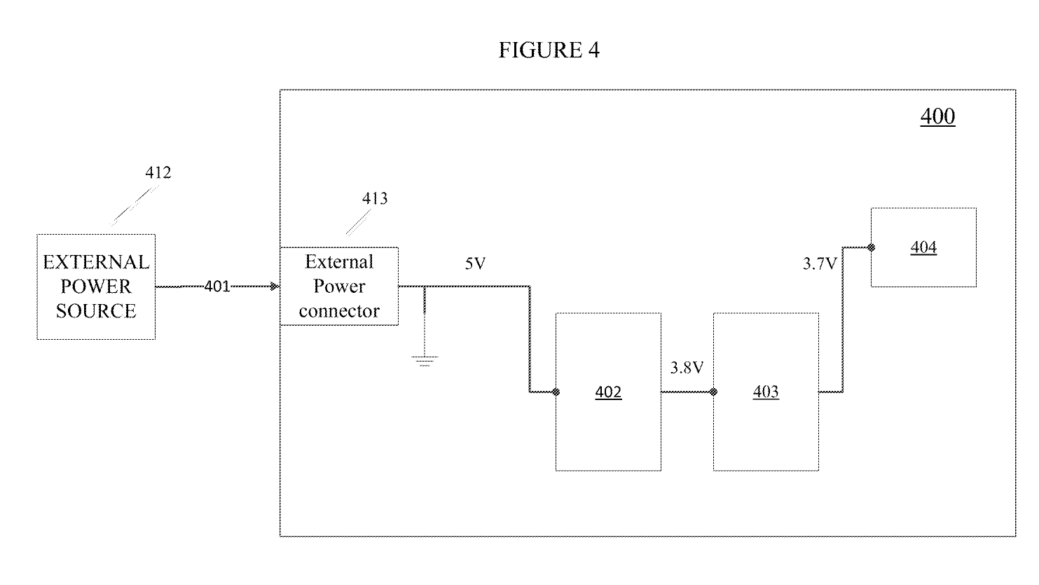

FIG. 4 illustrates an embodiment of an implementation of electronics 400 for the invented headphone system, in which amplifier 404 is powered by an internal rechargeable battery 403. An external power source 412 supplies power 401 through a power connector 413 to charging circuit 402. In this embodiment, amplifier 404 is always powered by battery 403 regardless of whether or not an external power source 412 is present. The external power source 412 is used to charge the battery 403. Amplifier 404 may comprise a single channel, multiple channels, or multiple amplifiers.

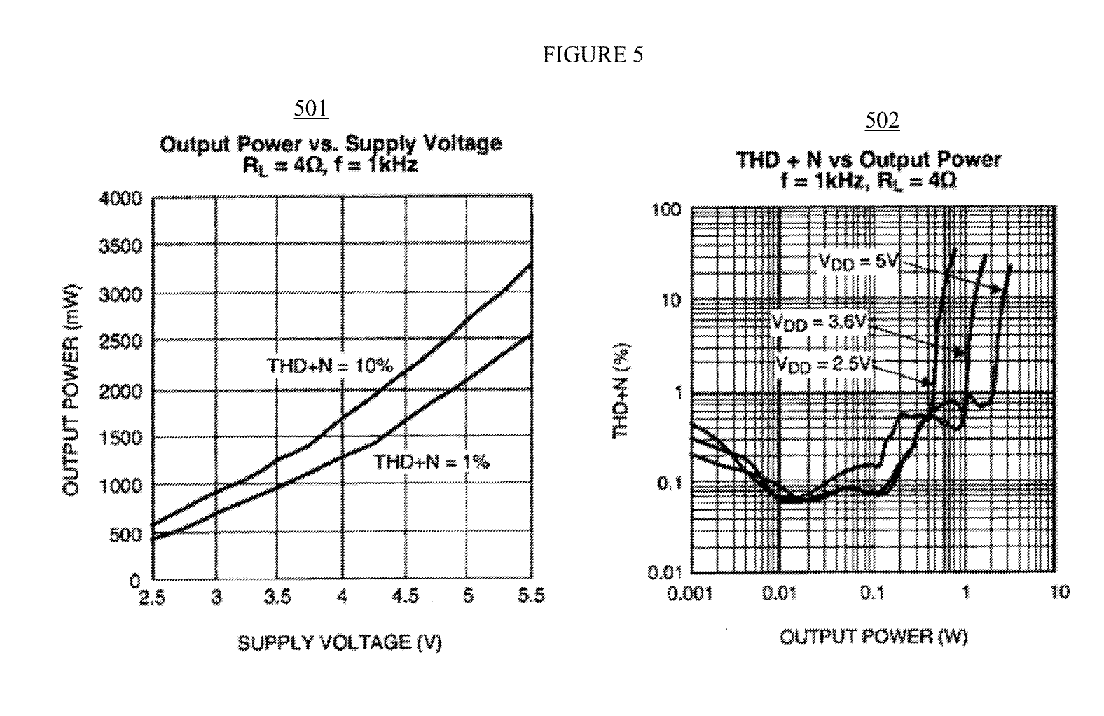

FIG. 5 illustrates exemplary graphs depicting the operational performance of an amplifier, according to aspects of the present disclosure. The output vs. supply voltage graph 501 illustrates that for a given distortion percentage, the output power of an amplifier is approximately two times higher when operated with a supply voltage of, for example 5V (e.g., the voltage supplied by a USB connection) versus a supply voltage of, for example 3.7V (e.g., the voltage supplied by a rechargeable Lithium battery). In addition, the distortion level vs. output power graph 502 illustrates that distortion, at a given output power, is approximately four times lower when the amplifier is operated at 5 Volts versus 3.7 Volts, thereby demonstrating performance has improved.

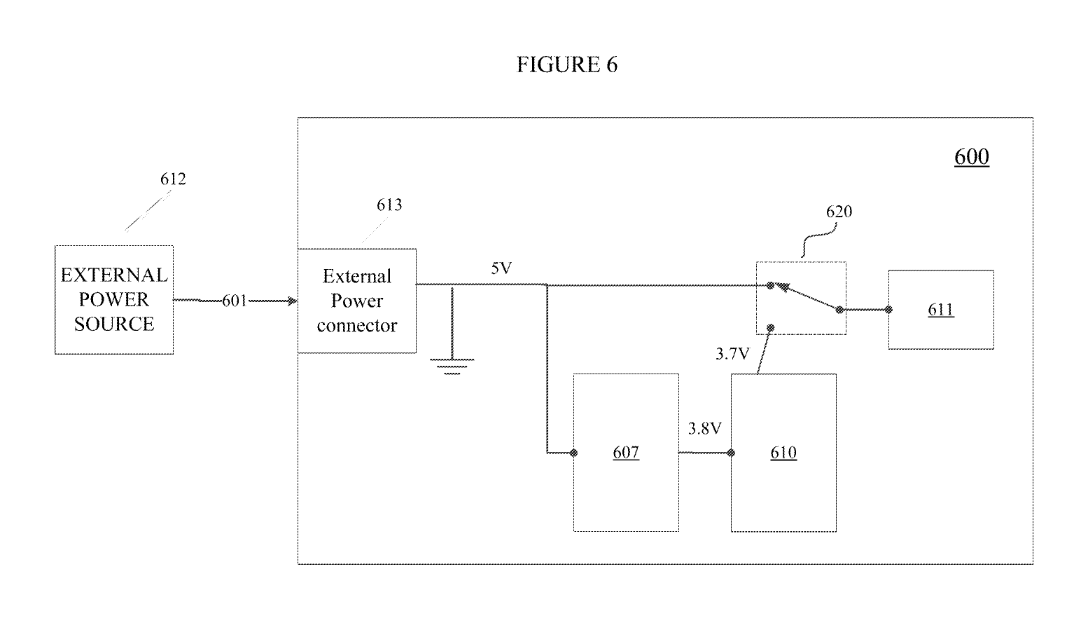

FIG. 6 illustrates exemplary headphone electronics 600 including a power diversion switch 620, according to embodiments of the present disclosure. When the headphone electronics 600 are disconnected from an external power source 612, the power diversion switch 620 is in the first condition (not shown) and connects the internal rechargeable battery 610 to the amplifier 611. When headphone electronics 600 is connected to the external power source 612 via power input receiver such as the external power connector 613, the power diversion switch 620 is in the second condition shown in FIG. 6 and sends the external power 601 directly to the amplifier 611. As shown in FIG. 6, when the external power source 612 is connected, the power diversion switch 620 disconnects the internal rechargeable battery 610 from the amplifier 611. When power 601 is supplied to the amplifier at a higher voltage than that derived from the internal power source 610, the output performance of amplifier 611 is improved. In addition, while the external power source 612 is connected to the headphone electronics 600, power 601 is provided to an optional battery recharging circuit 607 for charging the internal power source 610 (e.g., rechargeable battery). In another embodiment, the internal power source 610 comprises a non-rechargeable battery and recharging circuit 607 is eliminated.

As shown, the power diversion switch 620 is in the second condition having an external power source 612 (e.g., a computing device connectable to the headphone 600 via a USB connection) connected to headphone electronics 600 to provide an increased supply voltage 601 to amplifier 611. It is to be appreciated that any suitable connection between the external power source 612 and the headphone electronics 600 may be employed, external power connector 613 may not be needed. In an example, the voltage provided by the external power source is 5 Volts. One having ordinary skill in the art will appreciate that other supply voltage levels may be employed. Although the power diversion switch 620 is illustrated in combination with a rechargeable battery 610 the principal of supplying power to the amplifier 611 could be implemented with non-rechargeable primary batteries.

According to embodiments of the present disclosure, the power diversion switch 620 may be triggered in any stable manner, such as, for example, electronically or electromechanically (i.e., via a relay) upon direction of the external power supply 610. Alternatively, the power diversion switch 620 may be mechanically operated by the insertion force plug or other connection to the external power connector of the headphone 600.

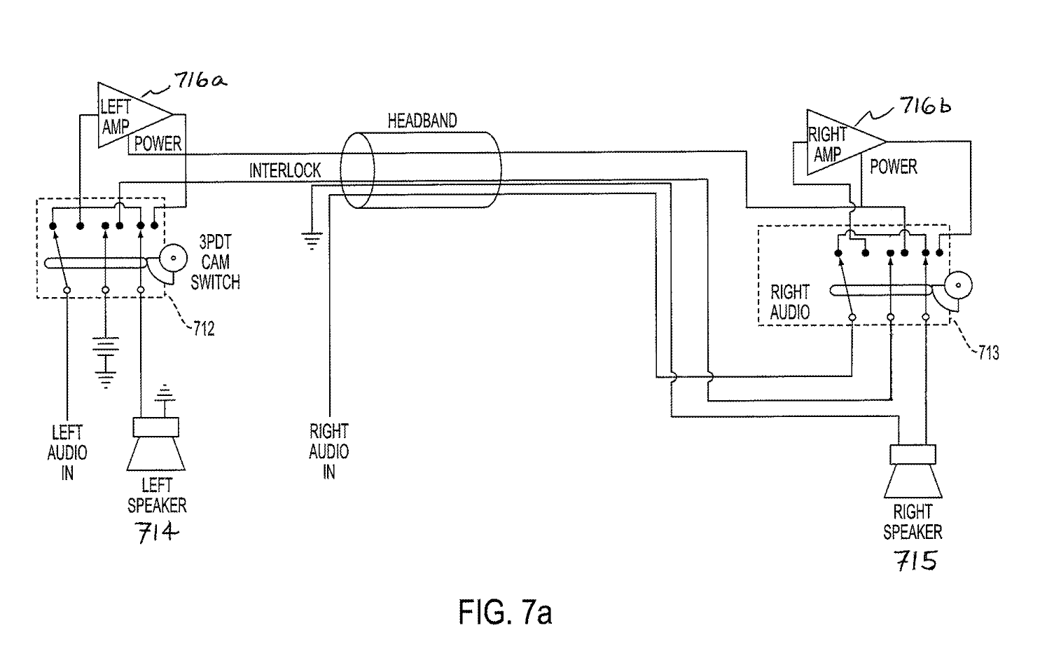

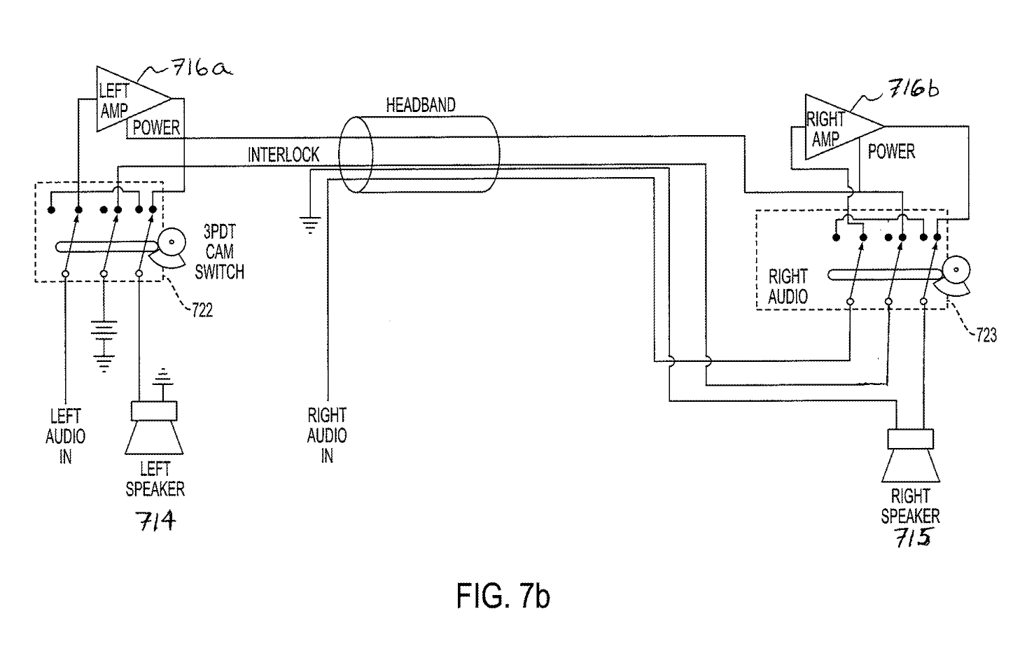

FIG. 7a and FIG. 7b illustrate exemplary embodiments of implementations of electronics for the invented headphone system, wherein the headphones have mode switches 712, 713, and 722, 723 respectively for each speaker 714, 715 of the headphone. Audio input receiver (not shown) (e.g., a cable, jack, or wireless receiver) receives an audio signal which is routed to the left audio in and the right audio in. When the axle is not rotated and the product is worn as a headphone, the mode switches 712, 713 connect the left audio in directly to the left speaker 714, and the right audio in to the right speaker 715, and does not route power to the amplifier(s) 716a, 716b, as illustrated in FIG. 7a. The music device powers the acoustic transducers (speakers 714, 715) directly. However, once the enclosures are rotated past a preset angle, switches 722 and 723 are thrown closed as illustrated in FIG. 7b. This now routes the left audio signal to the left amplifier 716a and the output of the left amplifier 716a to the left speaker 714 (and similarly for the right channel). It also provides power to the amplifier(s) 716a, 716b by running the power through the right enclosure switch 723 in series, thus assuring both switches 722, 723 must be closed (and thus the speakers aimed safely away from the ears) before energizing the amplifier(s). In another embodiment, the power diversion switch is integrated into the mode switch. In an additional embodiment, the power diversion switch is operated by at least one signal from the mode switch.

There are other variations and embodiments of the circuit. In another embodiment, the mode switch could contain one input and one output, used to trigger a solid state relay that provides all the aforementioned audio and power routing. In a further embodiment, the mode switch might be used to control the volume level, so it is low as a headphone and high as a speaker. This disclosure presents embodiments which can be used with any applicable circuitry and is not limited to the circuitry described.

The configurations and principles described above may be applied to a listening apparatus with only a single ear. In an embodiment, a headband is configured with a single speaker having two listening modes.

As used herein, the terms “example”, and/or “exemplary” are utilized to mean serving as an example, instance, or illustration. For the avoidance of doubt, the subject matter disclosed herein is not limited by such examples. In addition, any aspect or design described herein as an “example” and/or “exemplary” is not necessarily to be construed as preferred or advantageous over other aspects or designs, nor is limited to preclude equivalent exemplary structures and techniques known to those of ordinary skill in the art.

Numerous modifications and variations of the present disclosure are possible in light of the above teachings. It is therefore to be understood that within the scope of the attendant claims attached hereto, this disclosure may be practiced otherwise than as specifically disclosed herein.

What is claimed is:

1. A music playing and listening apparatus comprising:
at least one speaker, said speaker having at least two listening modes;
at least one mode switch;
at least one amplifier;
at least one power source; and
at least one power diversion switch.

2. The apparatus of claim 1 wherein said apparatus has a first power source, the first power source is integral to said apparatus.

3. The apparatus of claim 2 wherein said apparatus has a second power source, the second power source is external to said apparatus.

4. The apparatus of claim 1 wherein said apparatus has an audio input receiver.

5. The apparatus of claim 1 wherein said apparatus has a power input receiver.

6. The apparatus of claim 3 wherein said power diversion switch is configured to route power from said first power source to said amplifier in a first condition.

7. The apparatus of claim 6 wherein said power diversion switch is configured to route power from said second power source to said amplifier in a second condition.

8. The apparatus of claim 7 wherein performance of said amplifier is improved in said second condition.

9. A music playing and listening apparatus comprising:
a headband having opposing ends;
at least two connectors, each of said connectors having at least two arms, a first arm being shorter than a second arm;
at least two speakers, each of said speakers having opposing sides and comprising an audio output element on a first side and a compartment on a second side, said first and second arms of each of said connectors being pivotally attached to a portion of each of said speakers to thereby allow rotation of said speakers, each of said audio output elements of each of said speakers generally face one another during a first music listening mode, each of said speakers being rotatable about said first and second arms of each of said connectors to thereby allow each of said audio output elements of each of said speakers to turn away from one another during a second music playing mode; the rotation of said speakers allowing for changes in modes;
at least one amplifier; and
at least one power diversion switch.

10. The apparatus of claim 9 wherein said apparatus has a first power source, the first power source is integral to said apparatus.

11. The apparatus of claim 10 wherein said apparatus has a second power source, the second power source is external to said apparatus.

12. The apparatus of claim 9 wherein said apparatus has an audio input receiver.

13. The apparatus of claim 9 wherein said apparatus has a power input receiver.

14. The apparatus of claim 11 wherein said power diversion switch is configured to route power from said first power source to said amplifier in a first condition.

15. The apparatus of claim 14 wherein said power diversion switch is configured to route power from said second power source to said amplifier in a second condition.

16. The apparatus of claim 9 wherein performance of said amplifier is improved in said second condition.

17. A music playing and listening apparatus comprising:
a headband having opposing ends;
at least one connector, said connector having at least one arm;
at least one speaker, said speaker having opposing sides and comprising an audio output element on a first side and a compartment on a second side, said arm of said connector being pivotally attached to a portion of said speaker to thereby allow rotation of said speaker, said audio output element generally facing one direction during a first music listening mode, said speaker being rotatable about said arm of said connector to thereby allow said audio output element of said speaker to rotate to face a second direction during a second music playing mode;
the rotation of said speaker allowing for changes in modes;
at least one amplifier;
at least one power diversion switch; and
a first power source, wherein the first power source is integral to said apparatus; and
a power input receiver.
